(19) United States
(12) Patent Application Publication
(10) Pub. No.: US 2026/0002971 A1
(43) Pub. Date: Jan. 1, 2026

(54) DETECTING POWER LINE DISCONTINUITIES TO PROTECT AGAINST ARC FAULTS

(71) Applicant: Hamilton Sundstrand Corporation, Charlotte, NC (US)

(72) Inventors: Alex Gomes, Chicago, IL (US); Joshua C. Swenson, Rockford, IL (US)

(21) Appl. No.: 18/758,911

(22) Filed: Jun. 28, 2024

(51) Int. Cl. G01R 31/00

(52) U.S. Cl. CPC G01R 31/008

(57) ABSTRACT

An apparatus may include a solid-state power controller (SSPCs), a pulse generator, a feedback detector, and a microcontroller. The SSPC may be configured to output power from a power source to an aircraft electrical load. The pulse generator may be configured to generate a pulse through the SSPC. The pulse feedback detector may be configured to detect a response pulse from the generated pulse reflected from the aircraft electrical load, wherein the pulse feedback detector may be operably coupled to a power output of the SSPC. The microcontroller may be configured to trip the SSPC when the response pulse detected by a corresponding pulse feedback detector operably coupled to the SSPC is determined to be abnormal.

### TECHNICAL FIELD

This disclosure relates generally to aircraft devices and processes. More specifically, this disclosure relates to detecting power line discontinuities to protect against arc faults.

### BACKGROUND

During the operation of an aircraft, power wires may be subjected to faults or failures. While some of the faults or failures can be easily detected, other faults can be more challenging to detect.

### SUMMARY

This disclosure provides a method for detecting power line discontinuities to protect against arc faults.

In some embodiments, an apparatus may include a solid-state power controller (SSPC), a pulse generator, a feedback detector, and a microcontroller. The SSPC may be configured to output power from a power source to an aircraft electrical load. The pulse generator may be configured to generate a pulse through the SSPC. The pulse feedback detector may be configured to detect a response pulse from the generated pulse reflected from the aircraft electrical load, where the pulse feedback detector may be operably coupled to a power output of the SSPC. The microcontroller may be configured to trip the SSPC when the response pulse detected by the feedback detector operably coupled to the SSPC is determined to be abnormal.

Any single one or any combination of the following features may be used with the above embodiment. The microcontroller may be further configured to compare the response pulse to a calibrated response pulse for the SSPC when determining whether the response pulse is abnormal. To compare the response pulse to the calibrated response pulse, the microcontroller may be configured to compare key signal characteristics of the response pulse to key signal characteristics of the calibrated response pulse. The key signal characteristics of the calibrated response pulse may include at least one of a shape, an amplitude, a curve, a time, frequency domain harmonics, and a quantity of the pulse. To generate the pulse through the SSPC, the pulse generator may be configured to continuously generate the pulse at a predetermined interval. To generate the pulse through the SSPC, the pulse generator may be configured to generate the pulse based on a trigger. The pulse feedback detector may be further configured to generate the trigger based on identifying an abnormal voltage or abnormal current. The microcontroller may be further configured to receive an input for entering a calibration mode to identify calibrated response signals and activate the pulse generator. The microcontroller may be further configured to deactivate the pulse generator after a specified number of pulses have been identified by the pulse feedback detector and determine a calibrated response signal based on response pulses received by the pulse feedback detector for the specified number of pulses. The microcontroller may be further configured to store key signal characteristics of the calibrated response signals.

In other examples, a method may include outputting, using an SSPC, power from a power source to an aircraft electrical load. The method may also include generating, using a pulse generator, a pulse through the SSPC. The may method further include detecting, by a pulse feedback detector, a response pulse from the generated pulse reflected from the aircraft electrical load, where the pulse feedback detector may be operably coupled to a power output of the SSPC. In addition, the method may include tripping, using a microcontroller, the SSPC when the response pulse detected by the pulse feedback detector operably coupled to the SSPC is determined to be abnormal.

Any single one or any combination of the following features may be used with the above embodiment. The method may further include comparing, using the microcontroller, the response pulse to a calibrated response pulse for the SSPC when determining whether the response pulse is abnormal. Comparing the response pulse to the calibrated response pulse may include comparing key signal characteristics of the response pulse to key signal characteristics of the calibrated response pulse. The key signal characteristics of the calibrated response pulse may include at least one of a shape, amplitude, curve, time, frequency domain harmonics, and quantity of the pulse. Generating the pulse through the SSPC may include continuously generating the pulse at a predetermined interval. Generating the pulse through the SSPC may include generating the pulse based on a trigger. The method may further include generating, using the pulse feedback detector, the trigger based on identifying an abnormal voltage or abnormal current. The method may further include receiving an input for entering a calibration mode to identify calibrated response signals and activating the pulse generator. The method may further include deactivating the pulse generator after a specified number of pulses have been identified by the pulse feedback detector and determining a calibrated response signal based on response pulses received by the pulse feedback detector for the specified number of pulses. The method may further include storing key signal characteristics of the calibrated response signals.

Other technical features may be readily apparent to one skilled in the art from the following figures, descriptions, and claims.

### BRIEF DESCRIPTION OF THE DRAWINGS

For a more complete understanding of this disclosure, reference is made to the following description, taken in conjunction with the accompanying drawings, in which:

FIG. 1 illustrates an example fault detection system for detecting power line discontinuities to protect against arc faults in accordance with this disclosure; and

FIG. 2 illustrates an example method for detecting power line discontinuities to protect against arc faults according to this disclosure.

### DETAILED DESCRIPTION

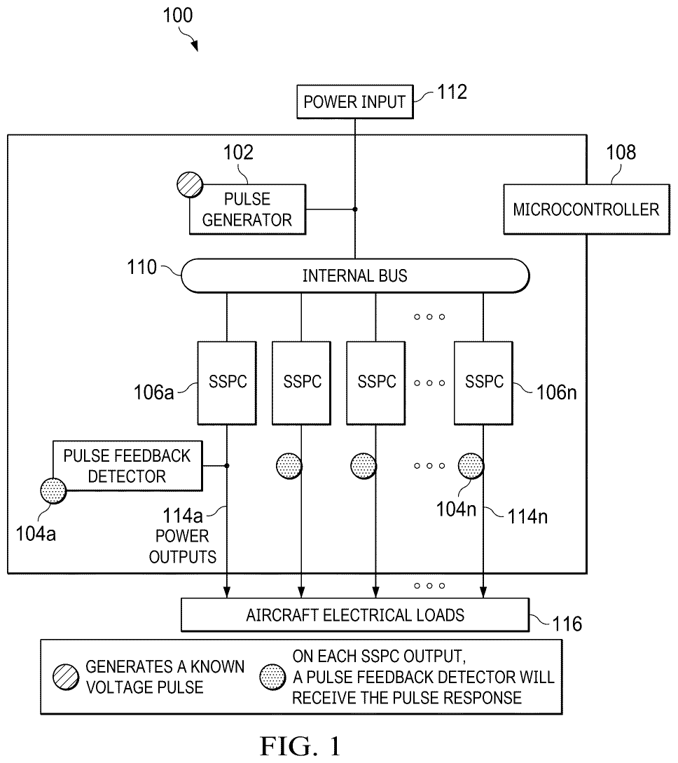

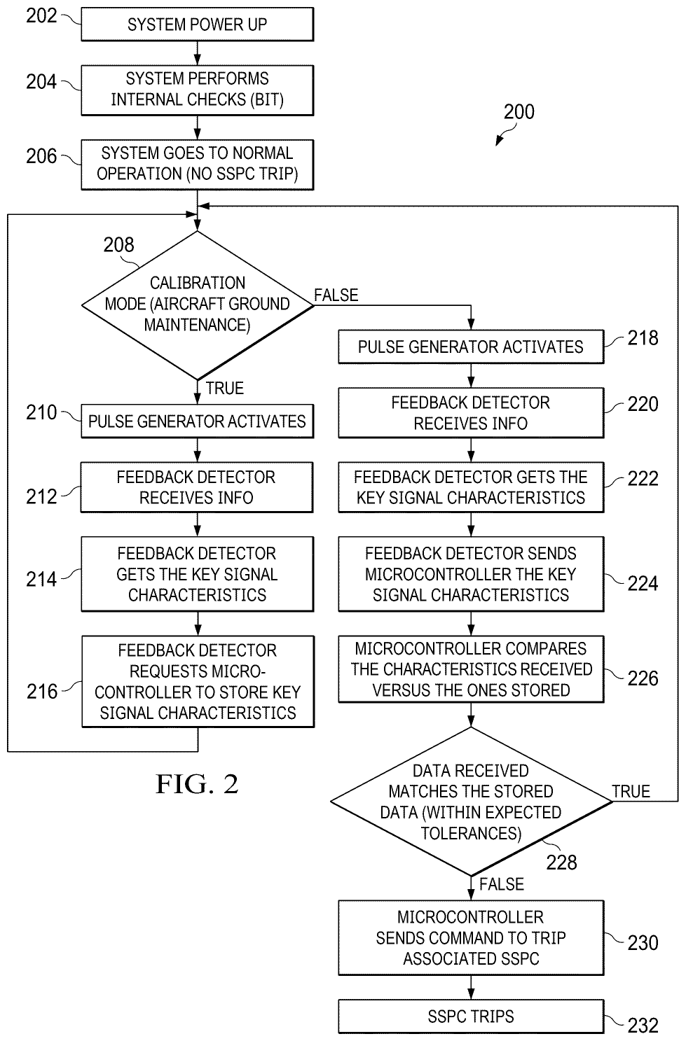

FIGS. 1 and 2, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

As described above, some faults in power wires of an aircraft can be challenging to properly detect and address. For example, a loss of terminal lug torque on terminal blocks between power sources and electrical loads can be hard to detect because the position is hard to access. Previous systems may not be able to provide adequate protection to minimize distress to an electrical system and hazard to the aircraft in the event of a wiring fault. This disclosure provides techniques to detect and consequently protect against interconnecting wiring faults downstream of a power source and upstream of a load.

FIG. 1 illustrates an example fault detection system 100 for detecting power line discontinuities to protect against arc faults in accordance with this disclosure. As shown in FIG. 1, the fault detection system 100 can detect power line discontinuities to protect against arc fault. To achieve this objective, the fault detection system 100 can apply a two-fold method. First, a pulse generator 102 can send a pulse or series of pulses with a known shape, amplitude, curve, time, quantity, etc. Second, the pulse(s) can spread downstream of the pulse generator 102 to the interconnecting wiring environment and pulse feedback detectors 104a-104n can read response pulses from an interconnecting wiring network. Upon detecting an abnormal response at one or more of the pulse feedback detectors 104a-104n, a microcontroller 108 can send the command for a solid state power controller (SSPC) 106a-106n (or any other protective device) to open the associated electrical circuit. The fault detection system 100 can include the pulse generator 102, the pulse feedback detectors 104a-104n, the SSPCs 106a-106n, the microcontroller 108, and an internal bus 110.

During normal operation, a power input 112, which may be for example, an AC or DC power supply, supplies current to the SSPCs 106a-106n. The SSPCs 106a-106n may be of any suitable type known in the art having a solid-state switch that responds to a current across the SSPCs 106a-106n. An SSPC typically has at least four operating conditions: an off condition, an on condition, a tripped condition, and a reset condition. For example, if the power supply is not energized and no current is being supplied to the SSPC 106a, the SSPC 106a is in the off condition. Additionally, if the power input 112 is operating and supplying a current, but a command signal is not present, the SSPC 106a is in the off condition. When the command signal is applied to an SSPC 106a with the power input 112 operating and supplying current, the SSPC 106a is in the on condition and provides power to an aircraft electrical load 116 on the power output 114a. If a fault condition occurs, i.e., the load current exceeds an over current set point or threshold, the SSPC 106a may detect the fault condition and enter the tripped condition, the current supply to the aircraft electrical load 116 is interrupted, and the SSPC 106a provides a trip signal to the microcontroller 108. The SSPC 106a can be in the reset condition and the trip signal can be removed if a command signal is removed and then reapplied after a reset delay period.

After an aircraft harness has been completed and quality confirmed (for example, from original equipment manufacturer quality assessment) and before normal operation, the fault detection system 100 can be started in a calibration mode. In the calibration mode, microcontroller 108 utilizes the pulse generator 102 to generate a pulse across the internal bus 110, the SSPCs 106a-106n, and power outputs 114a-114n to the aircraft electrical loads 116. The pulse generator 102 comprises the necessary signal conditioning and processing equipment to generate input signals, such as a pulse, which are provided to internal bus 110.

The pulse feedback detectors 104a-104n can detect a response pulse from each of the aircraft electrical loads 116 through respective power outputs 114a-114n. The response pulse is a reflection of the pulse by one or more of the aircraft electrical loads 116. The microcontroller 108 can analyze the response pulses detected by the pulse feedback detectors 104a-104n to calibrate the response pulse for each pulse feedback detectors 104a-104n. Each of the pulse feedback detectors 104a-104n can have a different calibrated response pulse corresponding to the differences in the circuitry downstream from each power output 114a-114n. Examples of differences in the circuitry can include different wiring impedances, routing, production breaks, loads, etc. If an SSPC 106a is replaced, the same calibration can be performed on the new SSPC 106a.

The calibration mode can be initiated by a user of the fault detection system 100. Once the calibration mode is initiated, continuous pulses can be generated in a known interval. The data collected by the pulse feedback detector 104a can be analyzed and key characteristics of the pulses can be stored in a non-volatile memory. During the calibration mode, no command may be sent to the SSPCs 106a-106n to open the electrical circuitry.

During an operation mode, the microcontroller 108 can identify an abnormal response pulse (from the pulse feedback detector) and send a command to an associated SSPC 106a to open the electrical circuitry. An abnormal response pulse can be identified based on comparing a response pulse identified during the operation mode to a corresponding calibrated pulse identified during the calibration mode. Different thresholds can be set for each condition of the response pulse evaluated. In certain embodiments, percentage or threshold ranges can be applied to all or individually identified calibration response pulses.

In certain embodiments, the pulse generator 102 can generate a pulse through the SSPCs 106a-106n to the power outputs 114a-114n continuously at a known interval for evaluation. The pulse feedback detector 104a-104n can continuously read the response pulses from the aircraft electrical loads 116.

In certain embodiments, the pulse generator 102 can be triggered based on an external trigger or command from the aircraft. The pulse feedback detector 104a-104n can read the response pulses from the aircraft electrical loads 116.

In certain embodiments, the pulse generator 102 can be triggered based on detecting changes in power characteristics of the voltage or currents. The pulse feedback detectors 104a-104n can read voltage and current of the circuitry and when the power characteristics are considered abnormal in regard to the system operation, the pulse generator 102 can send a pulse for the pulse feedback detectors 104a-104n to evaluate corresponding response pulses.

Although FIG. 1 illustrates one example of a fault detection system 100 for detecting power line discontinuities to protect against arc fault, various changes may be made to FIG. 1. For example, various components in FIG. 1 may be combined, further subdivided, replicated, omitted, or rearranged and additional components may be added according to particular needs. Also, the evaluation of the response pulses can vary widely based on the specific implementation.

FIG. 2 illustrates an example method 200 for detecting power line discontinuities to protect against arc faults according to this disclosure. For ease of explanation, the method 200 of FIG. 2 is described as being performed using the fault detection system 100 of FIG. 1. However, the method 200 may be used with any other suitable system and any other suitable aircraft.

As shown in FIG. 2, the fault detection system 100 powers up at step 202. The aircraft can initiate the power input 112 and power up the microcontroller 108, the pulse generator 102, the internal bus 110, the SSPCs 106a-106n, and the pulse feedback detectors 104a-104n.

The fault detection system 100 performs internal checks, such as built-in-tests, at step 204. When the fault detection system 100 determines that the internal checks pass, the fault detection system 100 proceeds with normal operation at step 206. For example, the internal checks pass when no SSPCs are in TRIP condition.

The fault detection system 100 determines whether calibration mode has been initiated at step 208. The calibration mode can be initiated by a user of the fault detection system 100. When determined to be in calibration mode, the fault detection system 100 begins calibrating the pulse feedback detectors 104a-104n.

The fault detection system 100 activates the pulse generator 102 in calibration mode at step 210. The pulse generator 102 generates a pulse through each SSPC 106a-106n to each power outputs 114a-114n connected to different aircraft electrical loads 116. The pulses can be generated continuously with a known pulse interval between subsequent pulses.

Each pulse feedback detector 104a-104n receives a response pulse from the aircraft electrical loads 116 at step 212. Each pulse feedback detector 104a-104n is individually connected to a corresponding power output 114a-114n of an SSPC 106a-106n. The pulse feedback detectors 104a-104n can determine when enough pulses have been identified to deactivate the pulse generator 102. The number of pulses can be determined for ending a calibration mode, or a variance threshold can be determined for each of the response pulses.

Each of the pulse feedback detectors 104a-104n identifies key signal characteristics of the response pulse at step 214. Key signal characteristics can include a shape, amplitude, curve, time, quantity, etc. The response pulses received by each pulse feedback detector 104a-104n can be different based on differences in the circuitry caused by one or more of different wiring impedances, routing, production breaks, and loads.

Each of the pulse feedback detectors 104a-104n provides the key signal characteristics for the calibrated response pulse to the microcontroller 108 for storage at step 216. The key signal characteristics can be stored in a non-volatile storage. After the key signal characteristics are stored, the fault detection system 100 can return to normal operation.

When determined to not be calibration mode in step 208, the fault detection system 100 begins controlling the pulse feedback detectors 104a-104n to detect a fault in the circuitry to the aircraft electrical loads 116.

The fault detection system 100 activates the pulse generator 102 at step 218. The pulse generator 102 generates a pulse through each SSPC 106a-106n to each power output 114a-114n connected to different aircraft electrical loads 116. The pulses can be generated continuously with a known pulse interval between subsequent pulses or the pulse generator 102 can be triggered by changes in power characteristics or external command.

Each pulse feedback detector 104a-104n receives a response pulse from the aircraft electrical loads 116 at step 220. Each pulse feedback detector 104a-104n is individually connected to a corresponding power output 114a-114n of an SSPC 106a-106n. The pulse feedback detectors 104a-104n can determine when enough pulses have been identified to deactivate the pulse generator 102. The number of pulses can be determined for deactivating the pulse generator 102 during the calibration mode, or a variance threshold can be determined for each of the response pulses.

Each of the pulse feedback detectors 104a-104n identifies key signal characteristics of the response pulse at step 222. Key signal characteristics can include a shape, amplitude, curve, time, quantity, etc. The response pulses received by each pulse feedback detector 104a-104n can be different based on differences in the circuitry caused by one or more of different wiring impedances, routing, production breaks, and loads.

Each of the pulse feedback detectors 104a-104n provides the key signal characteristics for the operating response pulse to the microcontroller 108 at step 224.

The microcontroller 108 can compare the operating response pulse to the calibrated response pulse at step 226. Each operating response pulse can be compared to a calibrated response pulse of a same pulse feedback detector 104a-104n because each pulse feedback detector is operably coupled to a respective power output 114a-114n. Thus, the operating response pulse and the calibrated response pulse are identified passing through the same circuitry to one or more respective aircraft electrical loads 116.

The microcontroller 108 can determine whether the operating response pulse and the calibrated response pulse are within expected tolerances at step 228. The expected tolerances can be based on thresholds for the key signal characteristics. The microcontroller 108 can determine an abnormal response pulse when the operating response pulse does not match a calibrated response pulse from a same power output 114a-114n. The differences can be based on one or more of the key signal characteristics being outside of a threshold range for a specified key signal characteristic. When the microcontroller 108 determines that the operating response pulse and the calibrated response pulse are within expected tolerances, the pulse generator 102 reactivates and the microcontroller 108 waits for the pulse feedback detector 104a-104n to receive more operating response pulses in step 206.

The microcontroller 108 can send a command to trip a respective SSPC 106a at step 230. The respective SSPC 106a is tripped in step 232. An indicator can be sent to an operator of the aircraft or a maintenance worker that the SSPC 106a has been tripped. The remaining pulse feedback detectors 104b-104n continue to monitor the respective SSPCs 106b-106n that are not tripped.

Although FIG. 2 illustrates one example of a method 200 for detecting power line discontinuities to protect against arc fault, various changes may be made to FIG. 2. For example, while shown as a series of steps, various steps in FIG. 2 may overlap, occur in parallel, or occur any number of times.

It may be advantageous to set forth definitions of certain words and phrases used throughout this patent document. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S.C. § 112 (f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. An apparatus comprising:
a solid-state power controller (SSPC) configured to output power from a power source to an aircraft electrical load;
a pulse generator configured to generate a pulse through the SSPC;
a pulse feedback detector configured to detect a response pulse from the generated pulse reflected from the aircraft electrical load, wherein the pulse feedback detector is operably coupled to a power output of the SSPC; and
a microcontroller configured to trip the SSPC when the response pulse detected by the pulse feedback detector operably coupled to the SSPC is determined to be abnormal.

2. The apparatus of claim 1, wherein the microcontroller is further configured to compare the response pulse to a calibrated response pulse for the SSPC when determining whether the response pulse is abnormal.

3. The apparatus of claim 2, wherein, to compare the response pulse to the calibrated response pulse, the microcontroller is configured to compare key signal characteristics of the response pulse to key signal characteristics of the calibrated response pulse.

4. The apparatus of claim 3, wherein the key signal characteristics of the calibrated response pulse include at least one of a shape, an amplitude, a curve, a time, frequency domain harmonics, and a quantity of the pulse.

5. The apparatus of claim 1, wherein, to generate the pulse through the SSPC, the pulse generator is configured to continuously generate the pulse at a predetermined interval.

6. The apparatus of claim 1, wherein, to generate the pulse through the SSPC, the pulse generator is configured to generate the pulse based on a trigger.

7. The apparatus of claim 6, wherein the pulse feedback detector is further configured to generate the trigger based on identifying an abnormal voltage or abnormal current.

8. The apparatus of claim 1, wherein the microcontroller is further configured to:
receive an input for entering a calibration mode to identify calibrated response signals; and
activate the pulse generator.

9. The apparatus of claim 8, wherein the microcontroller is further configured to:
deactivate the pulse generator after a specified number of pulses have been identified by the pulse feedback detector; and
determine a calibrated response signal based on response pulses received by the feedback detector for the specified number of pulses.

10. The apparatus of claim 8, wherein the microcontroller is further configured to store key signal characteristics of the calibrated response signals.

11. A method comprising:
outputting, using a solid-state power controller (SSPC), power from a power source to aircraft electrical load;
generating, using a pulse generator, a pulse through the SSPC;
detecting, by pulse feedback detector, a response pulse from the generated pulse reflected from the aircraft electrical load, wherein the pulse feedback detector is operably coupled to a power output of the SSPC; and
tripping, using a microcontroller, the SSPC when the response pulse detected by the pulse feedback detector operably coupled to the SSPC is determined to be abnormal.

12. The method of claim 11, further comprising:
comparing, using the microcontroller, the response pulse to a calibrated response pulse for the respective SSPC when determining whether the response pulse is abnormal.

13. The method of claim 12, wherein comparing the response pulse to the calibrated response pulse comprises comparing key signal characteristics of the response pulse to key signal characteristics of the calibrated response pulse.

14. The method of claim 13, wherein the key signal characteristics of the calibrated response pulse include at least one of a shape, amplitude, curve, time, frequency domain harmonics, and quantity of the pulse.

15. The method of claim 11, wherein generating the pulse through the SSPC comprises continuously generating the pulse at a pre-determined interval.

16. The method of claim 11, wherein generating the pulse through the SSPC comprises generating the pulse based on a trigger.

17. The method of claim 16, further comprising:
generating, using the pulse feedback detector, the trigger based on identifying an abnormal voltage or abnormal current.

18. The method of claim 11, further comprising:
receiving an input for entering a calibration mode to identify calibrated response signals; and
activating the pulse generator.

19. The method of claim 18, further comprising:
deactivating the pulse generator after a specified number of pulses have been identified by each of the pulse feedback detector; and
determining a calibrated response signal based on response pulses received by the pulse feedback detector for the specified number of pulses.

20. The method of claim 18, further comprising:
storing key signal characteristics of the calibrated response signals.
